(19) United States
(12) Patent Application Publication
(10) Pub. No.: US 2010/0065260 A1
(43) Pub. Date: Mar. 18, 2010

(54) VIBRATION GENERATING AND COOLING APPARATUS

(76) Inventors: Hitoshi Sakamoto, Tokyo (JP); Kazuyuki Mikubo, Tokyo (JP); Takeya Hashiguchi, Tokyo (JP)

Correspondence Address: Mr. Jackson Chen, 6535 N. STATE HWY 161, IRVING, TX, 75039, US

(21) Appl. No.: 12/529,438

(22) PCT Filed: Feb. 21, 2008
(86) PCT No.: PCT/JP2008/053001

§ 371 Date: Sep. 1, 2009

(30) Foreign Application Priority Data
Mar. 20, 2007 (JP) 2007-073573

(51) Int. Cl. H05K 7/20; F04D 25/02

(52) U.S. Cl. 165/121; 417/321

(57) ABSTRACT

There is provided an energy-saving vibration generating and cooling apparatus with a small volume in which convection is created inside and outside its cabinet and which can effectively transfer heat. It includes a motor 4, a magnetic vibrator 1 mounted onto a rotary shaft of the motor 4, and a piston 5 indicating magnetism disposed physically apart from the vibrator 1; and the piston 5 repeatedly approaches and leaves the vibrator 1 in association with rotations of the vibrator 1 such that a heat generating element is cooled by a synthetic jet 7 created by the movement of the piston 5.

### TECHNICAL FIELD

The present invention relates to an apparatus to cool a heat generating source in equipment of electronic devices, and in particular, to a cooling apparatus which employs a vibration generator and which is mounted in an electronic device.

### RELATED ART

With recent progress of technologies, portable electronic apparatuses are increasingly being downsized; on the other hand, both of the calorific value and calorific density tend to become greater due to developed efficiency of the apparatuses and high-density mounting of electronic parts.

In electronic apparatuses such as portable telephone terminals of which the size is particularly reduced, it is quite difficult to mount a mechanism to diffuse heat generated in a cabinet; even if the mechanism is mounted, it is difficult to efficiently convect air in the cabinet of which the size as well as thickness are remarkably reduced.

One of the reasons therefor will be that it is difficult to secure in the cabinet a space required to mount a fan and the like. In addition to a fan section which actually generates wind, there is also required a motor to generate rotational force; in a case of a general fan in which a motor is installed on a center of rotating blades, its diameter is ten mm or more and its size is almost equivalent to thickness of portable terminal apparatuses.

Patent Document 1 discloses a configuration in which fan blades are attached to an axle of a vibration generating motor beforehand mounted in a portable telephone terminal or the like. This is a configuration in which the fan blades also rotate according to the motor rotation. A vibrator is coupled with the motor by “clutch mechanism” according to necessity.

In this configuration, a certain clutch mechanism is required; in addition, since the vibrator and the clutch mechanism are on the lee side of the fan, it is necessary to keep a wind flow rate by increasing the diameter of the fan.

To make it compact by removing gears, it will be considered to connect the motor, the vibrator, and the fan blades in series. However, for the portable-type electronic devices for which the downsizing is underway, the space in the devices is increasingly becoming quite smaller; hence, it is likely that the motor interrupts the air flow in the arrangement.

Also, the principle to cause the air flow is the same as that of the rotating fun of conventional type; basically, the size thereof is only reduced.

Patent Document 2 discloses a construction in which fan blades of vibration generator built-in type is arranged at the lee-most position. By use of the construction in which the fan blades can be rotated according to the motor rotary direction, the clutch mechanism is simplified. However, it is inevitable that as for the volume in the cabinet, the volume to mount the fan is additionally required.

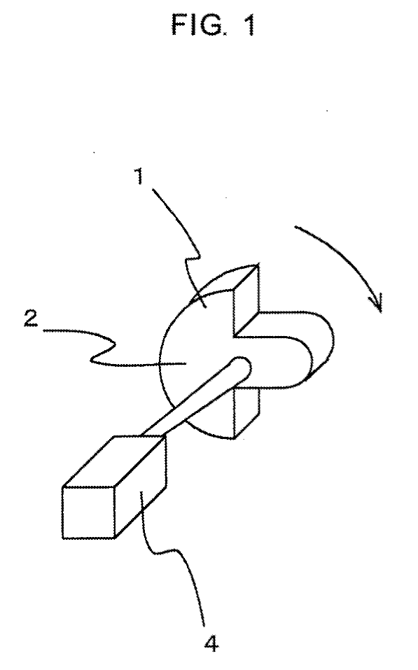

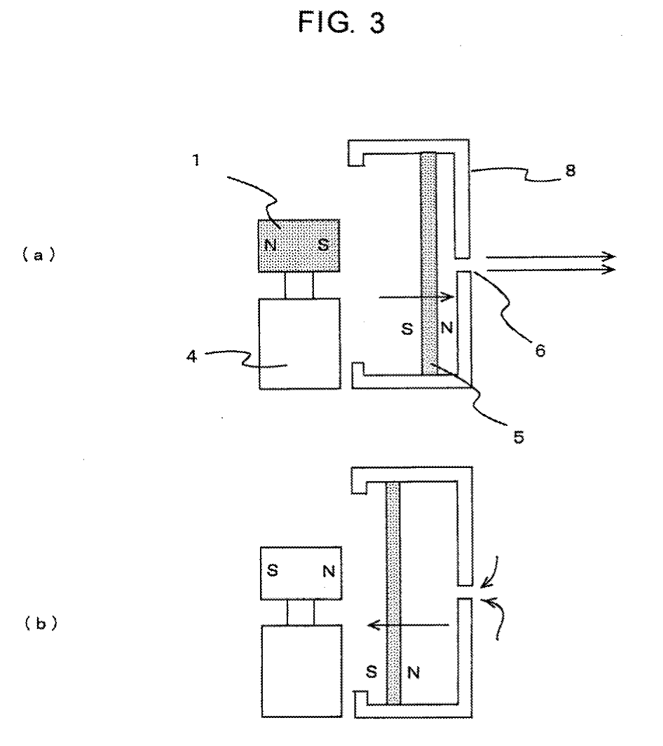

Patent Document 3 proposes a swing-type fan employing a piezoelectric element. By adopting a piezoelectric element, the apparatus to be mounted additionally includes new power consuming parts and heat generating elements. Also, an electric circuit to manage operation of the piezoelectric element is required to be arranged. Moreover, the wind flow rate is restricted by quantity of deformation of the piezoelectric element having relatively high rigidity.
Patent Document 1: Japanese Patent Laid-Open Pub. No. 2000-252667 (FIGS. 1 to 4)
Patent Document 2: Japanese Patent Laid-Open Pub. No. 2006-280104 (FIGS. 3, 6, and 7)
Patent Document 3: Japanese Patent Laid-Open Pub. No. 2002-134975
Patent Document 4: Japanese Patent Laid-Open Pub. No. Hei 7-243738

### DISCLOSURE OF THE INVENTION

### Problem to be Solved by the Invention

For recent portable-type electronic apparatuses designed in micron units, the removal of the cooling problem is an important issue; to keep predominance in the market of apparatuses, it is essential that they are small in size. In these apparatuses of which performance is being enhanced, the cooling construction which relies upon heat conduction is approaching its limit today.

Patent Document 4 discloses an invention in which a cooling medium is sealed in a tube such that by vibrating the tube, heat conduction is urged; however, in a portable terminal of which size and weight are required to be reduced, it is difficult that the tube is installed in the terminal and the liquid as the cooling medium is kept in the terminal. That is, the configuration of the invention disclosed by Patent Document 4 is not applicable to portable terminals.

The present invention has been devised in consideration of these problems and aims to provide an energy-saving vibration generating and cooling apparatus with a small volume in which convection is caused inside and outside its cabinet by use of a mechanism to generate vibration and which can efficiently transfer heat.

### Means for Solving the Problem

To achieve the above object, the present invention provides a vibration generating and cooling apparatus, characterized by including a motor, a magnetic eccentric plummet mounted onto a rotary shaft of the motor, and a magnetic member indicating magnetism disposed physically apart from the eccentric plummet, wherein the magnetic member repeatedly approaches and leaves the eccentric plummet in association with rotations of the eccentric plummet and a to-be-cooled object is cooled by a jet created by the movement of the magnetic member.

In the present invention, it is favorable that the magnetic member is a diaphragm arranged to enclose a predetermined space excepting at least one nozzle section, and when the diaphragm deforms in association with the rotations of the eccentric plummet, fluid in the predetermined space is ejected as the jet from the nozzle section and is blown onto the to-be-cooled object.

Moreover, in accordance with the present invention, it is favorable that the magnetic member is a piston arranged to enclose a predetermined space excepting at least one nozzle section, and when the piston is dislocated in association with the rotations of the eccentric plummet, fluid in the predetermined space is ejected as the jet from the nozzle section and is blown onto the to-be-cooled object. In addition, the piston is favorably monoblock-molded using a magnetic substance and a resin material. Also, more favorably, at least one of the nozzle sections is arranged to generate the jet in a direction different from a stroke direction of the piston.

Alternatively, in the present invention, it is favorable that the magnetic member is a swing fan disposed in a duct physically connected to a heat generating element and a jet generated in the duct when the swing fan swings in association with the rotations of the eccentric plummet cools the duct heated through heat conduction from the heat generating element; additionally, more favorably, projections and depressions are formed on an inner wall surface of the duct.

### Advantages of the Invention

In accordance with the present invention, it is possible to provide an energy-saving vibration generating and cooling apparatus with a small volume in which a convention is caused inside and outside its cabinet by use of a mechanism to generate vibration and which efficiently transfers heat. It is hence possible to mount more efficient electronic parts while coping with the downsizing of apparatuses.

### BEST MODE FOR CARRYING OUT THE INVENTION

### First Exemplary Embodiment

Description will be given of a first exemplary embodiment favorably carrying out the present invention by referring to drawings.

FIG. 1 is a perspective view showing a configuration of a vibration generator. This vibration generator adopts a magnet 2 as a vibrator 1. The vibrator 1 is formed in a shape of an eccentric plummet and generates vibration on the basis of the high rotation of a motor 4 and quantity of eccentricity of the plummet. Magnitude of the generated vibration expressed by the maximum acceleration of the vibrator 1 is in proportion to the weight of the plummet and distance from the vibrator 1 to the center of gravity of the plummet and is in proportion to the square of the rotary speed. Therefore, in a cooling operation, if the motor 4 is turned with a rotary speed of, for example, one fourth of an original speed, the vibration magnitude is one sixteenth of original magnitude. Moreover, when the cooling construction which functions in response to the movement of the magnet is configured to suppress resonance in a high-rotary-speed range, a changeover between a vibration generator and a cooling device can be easily carried out only by altering the number of rotations of the motor 4.

As an example of the cooling construction responding to the magnet movement, description will be given of a method employing a synthetic jet. By moving a piston or the like in the sealed configuration excepting an opening for exhaust and intake, a flow passing the opening is generated by use of a change in the volume of the sealed construction.

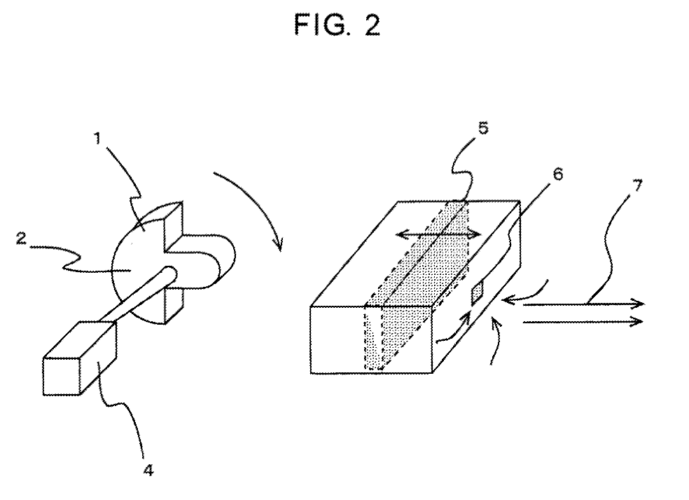

FIG. 2 shows a concept of the synthetic jet. A synthetic jet 7 is a jet generating device in which one opening (a nozzle 6) is used for an intake opening and an exhaust opening; hence, the net flow rate is zero because the intake and the exhaust use the same opening. Also, excepting the surface including the intake and exhaust opening, it is not required to dispose any opening for the flow. For the intake, the fluid in the periphery of the nozzle 6 are sucked; for the exhaust, the fluid is discharged with a directivity at a relatively high flow speed. By disposing an electronic part as a heat generating element at a destination of the jet flow, the cooling effect is attained.

In the intake, air in the vicinity of the nozzle 6 is sucked; in the exhaust, the air is discharged linearly from the nozzle 6 toward a distant point; hence, quite a small amount of air in the cabinet can be efficiently circulated.

The vibration generator in accordance with the present embodiment is applicable to a small-sized electronic apparatus in which the conventional cooling mechanism using the convection cannot be easily mounted. In a cooling construction in which heat is transferred to the cabinet primarily through the heat conduction, there exists a problem that the cabinet is locally heated to a high temperature; however, in the present embodiment, a flow of air is generated in the sealed space in the cabinet; hence, in addition to the cooling of the electronic part, there is attained an advantage that the surface temperature of the cabinet is uniform.

As FIG. 3 shows, by adopting a magnetic substance as a piston 5 for the operation, it is possible to operate the piston 5 in response to the magnet 2 of the vibrator 1. It is favorable that to lower the piston 5 in weight by molding it with a resin material into a monoblock so that the piston 5 operates even with the limited magnetic force.

When a cylinder having a diameter of 10 mm and a stroke of 1 mm is formed and the vibrator 1 is rotated with the number of rotations of 1000 turns per minute which is equal to or less than one tenth of that for the vibration generation, a jet flow equal to or more than 40 cm per second can be generated even if the contour of the nozzle 6 is limited to 1 mm×3 mm. This indicates that, when compared with an 8 mm square small-sized fan, a flow speed of about 40% is attained while lowering the number of turns to one fifteenth.

For the small-sized fan, although the thickness of the fan itself is reduced to 2 mm, the thickness direction is the wind flowing direction; hence, it is required to dispose a space to flow the wind; in consideration of a thin-type device cabinet, it is quite difficult to employ an arrangement in which the heat generating element is placed in the wind flowing direction.

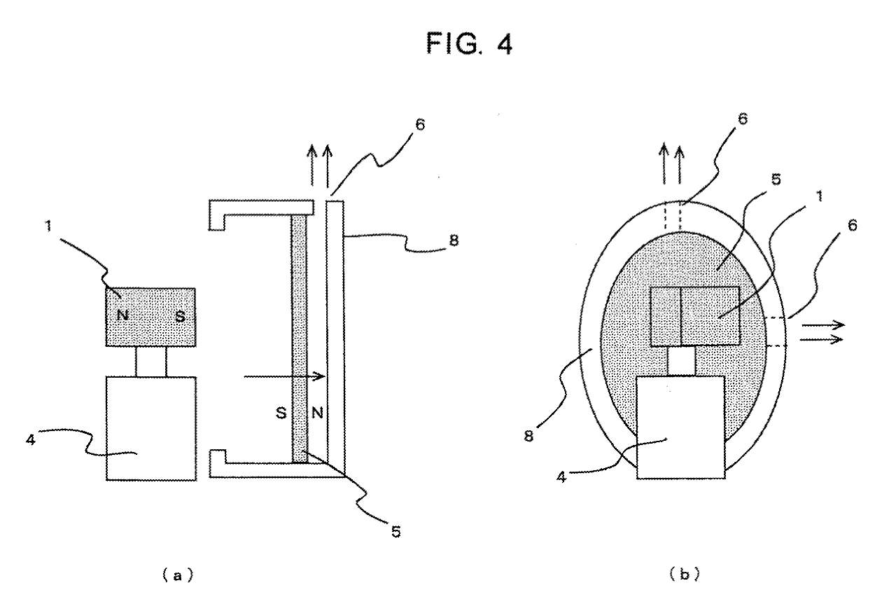

For the synthetic jet 7, it is not required to arrange the nozzle 6 in the vibrating direction of the piston 5; as shown in FIG. 4(a), it can generate the jet flow in an arbitrary direction such as a lateral direction with respect to the vibrating direction of the piston 5, and hence it is possible to cope with a limited space in the thin-type cabinet. Further, if the to-be-cooled object exists at two or more places, they can be directly cooled by the jet flow by arranging a plurality of openings 6 to generate the jet flow as shown in FIG. 4(b). In the case of a fan, although it is small in size, it can generate the wind in only one direction; therefore, to blow wind in a plurality of directions, it is inevitable to construct a duct.

In the vibration generator according to the present embodiment, an air flow having stirring effect in the cabinet can be generated by use of quite a small space in the electronic device. That is, the size thereof can be reduced when compared with the configuration in which a fan is mounted. Moreover, by altering the synthetic jet diameter (the nozzle contour), the flow speed is changeable while keeping the flow rate unchanged; hence, the cooling effect can be more efficiently attained when compared with the construction in which the fan diameter directly affects the flow rate.

### Second Exemplary Embodiment

Description will be given of a second exemplary embodiment which favorably embodies the present invention.

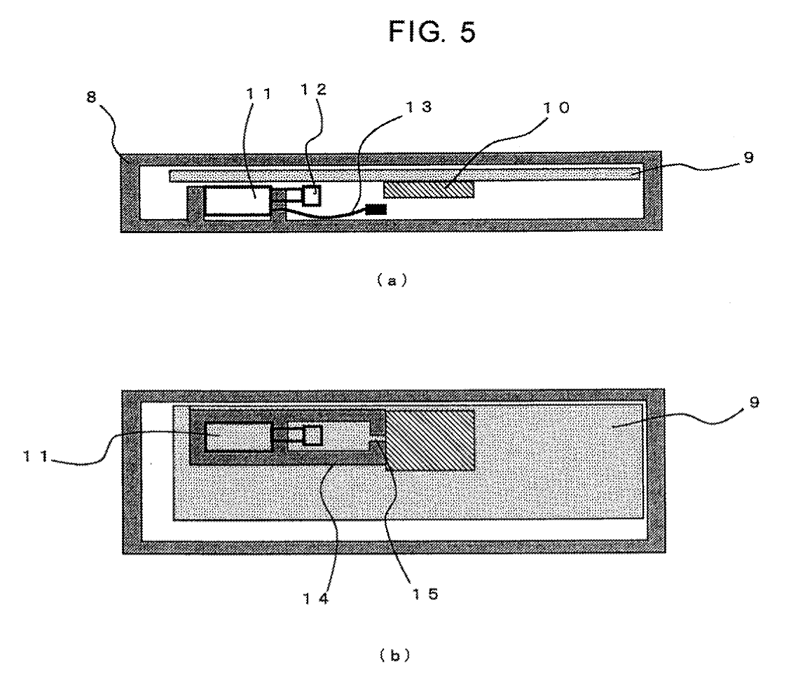

In this embodiment, the vibration unit which operates in response to the magnet vibrator is implemented by a diaphragm. In the configuration, the abrasive resistance which takes place during the operation of the piston is removed, and it is possible to simplify the construction by directly mounting the diaphragm itself on the inner wall of the cabinet. FIG. 5 shows a configuration of a cooling module in accordance with the present embodiment.

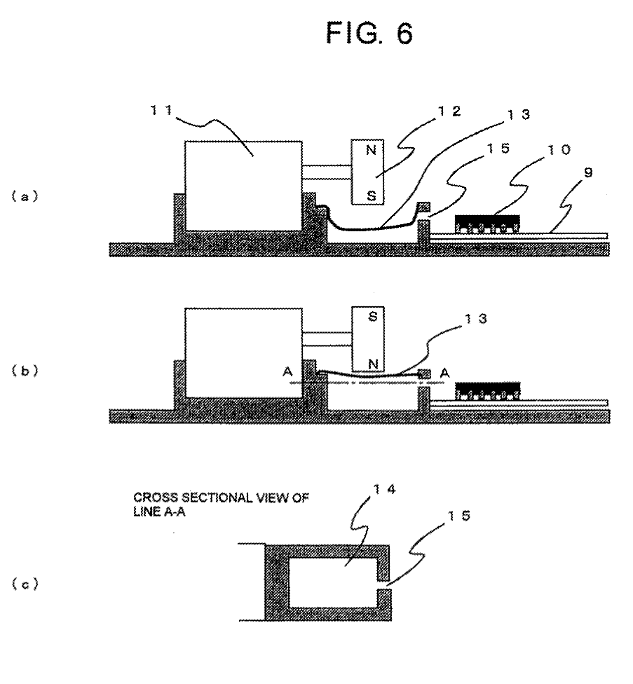

In general, a projecting section onto which a diaphragm 13 is to be attached is disposed on an inner surface of a cabinet 8 on the side of a vibrator 12 of a motor 11 held by the cabinet 8 inside the cabinet. A nozzle 15 is formed by not arranging the projecting section partially on the inner surface which faces an electronic part mounted on a printed board 9. And as FIG. 6 shows, according to the motion of the diaphragm 13, air is sucked and is discharged using a space (air reservoir) 14 enclosed by the diaphragm 13, the projecting section, and the cabinet 8.

It is ideal to adopt a thin, flexible magnet sheet for the diaphragm 13. There has been developed a 1 mm thick magnet sheet which is produced through monoblock-molding by use of powder of a magnetic substance and which has flexibility and elasticity. By adhering such magnet sheet onto the projecting section of the cabinet inner wall, the volume of the cylinder construction for jet generation can be minimized.

As for the magnetic force, although depending on the sheet thickness, since the sheet-shaped magnet is made to swing in the present embodiment, sufficient effect is attainable even if the thickness is equal to or less than 1 mm. Hence, it is favorable to provide flexibility to the sheet including a magnetic material which is inherently not flexible by reducing the sheet thickness to 0.5 mm or less.

### Third Exemplary Embodiment

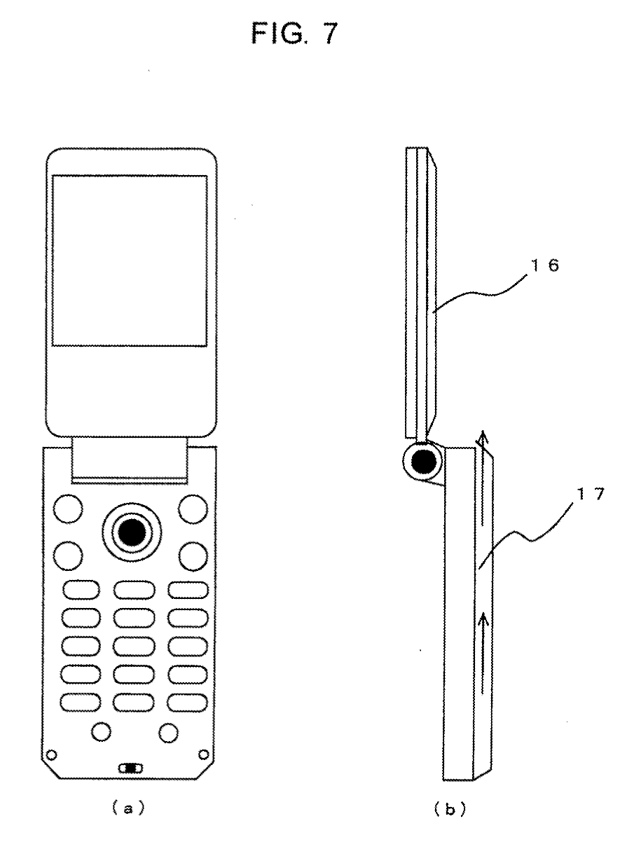

Description will be given of a third exemplary embodiment which favorably embodies the present invention. FIG. 7 shows an outer appearance of a mobile telephone terminal to which a vibration generator in accordance with the present embodiment is applied. In the present embodiment, heat is efficiently dissipated through natural convection outside the cabinet.

As shown here, even for a small-sized electronic device such as a mobile telephone terminal 16, it is possible, by disposing a duct 17, to effectively collect heat on an inner wall of the duct 17. Hence, if cooling convection can be efficiently caused in the duct 17, a flow can be generated outside the cabinet by use of a magnet vibrator 1 arranged in the cabinet.

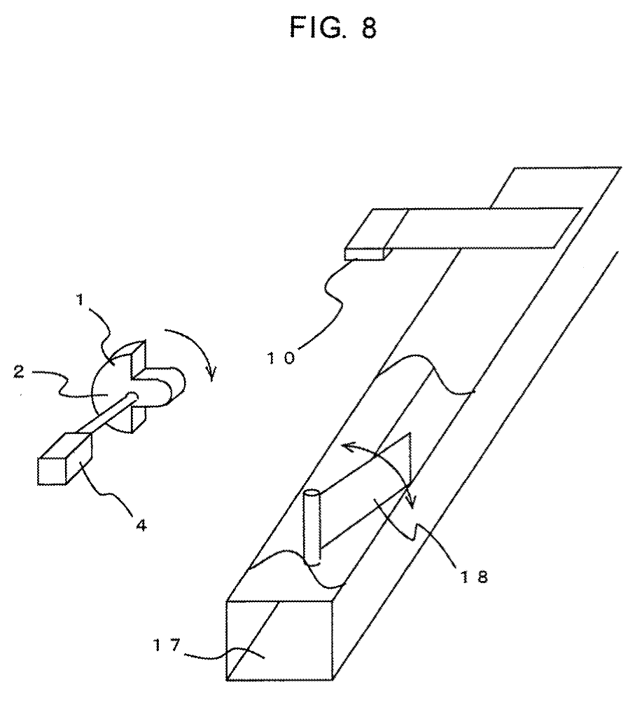

As FIG. 8 shows, when a sheet-shaped, highly-heat-conductive substance is employed as a heat dissipating section from a heat generating element 10 up to the duct 17, it is possible to transfer heat. In the cooling construction in which heat is conducted from the heat generating element to the cabinet as the heat dissipating section, it is likely that temperature on an outer surface of the cabinet is equal to or more than a prescribed value; however, in the construction of the present embodiment, even if the inner wall of the duct 17 reaches a prescribed temperature, the outer side of the duct 17 can be kept at a temperature equal to or less than the prescribed value.

Further, the availability of a high inner surface of the duct 17 (a great surface area of the inner surface) is advantageous to transfer heat to the air passing through the duct 17.

FIG. 5 shows a configuration of the cooling duct 17 in which a reciprocal-type fan 18 operating in association with the vibrator 1 including the magnet is mounted. By using the fan 18 of reciprocal-motion type, it is not required to arrange a rotary shaft and the like in the duct 17, and it is hence possible to strengthen immunity also against the incoming of dust or the like.

In this way, by use of a magnet as the vibrator, the cooling mechanism can be operated without using mechanical connection. Hence, when a reciprocal-type fan is disposed in the cooling duct arranged outside the cabinet, the fan outside the cabinet can be operated by using a vibration generator existing inside the cabinet having a dustproof and waterproof function.

The respective exemplary embodiments described above are favorable examples of the present invention, and the present invention is not restricted by them.

For example, the present invention is applicable not only to the mobile telephone terminal, but also to any portable-type electronic apparatus in which a semiconductor device is employed such as a notebook-type computer, a portable-type game machine, a portable-type reproducer, or a PDA.

In this fashion, various variations are possible for the present invention.

This application is based upon and claims the benefit of priority from Japanese patent application No. 2007-073573, filed on Mar. 20, 2007, the disclosure of which is incorporated herein in its entirety by reference.

### BRIEF DESCRIPTION OF DRAWINGS

[FIG. 1] is a perspective view showing a configuration of a vibration generator.

[FIG. 2] is a diagram showing a concept of a synthetic jet.

[FIG. 3] is a diagram showing a configuration of a cooling device in accordance with a first exemplary embodiment employing a magnetic substance for a piston.

[FIG. 4] is a diagram showing a configuration of a cooling apparatus to generate a jet flow in a lateral direction with respect to vibration of a piston and a configuration of a cooling apparatus to generate a plurality of jet flows.

[FIG. 5] is a diagram showing a configuration of a cooling apparatus in accordance with a second exemplary embodiment favorably carrying out the present invention.

[FIG. 6] is a diagram showing operation of a cooling apparatus in accordance with the second exemplary embodiment.

[FIG. 7] is a diagram showing an outer appearance of a mobile telephone terminal in which a cooling apparatus in accordance with a third exemplary embodiment favorably carrying out the present invention is mounted.

[FIG. 8] is a diagram showing a configuration of a cooling apparatus in accordance with the third exemplary embodiment.

### DESCRIPTION OF REFERENCE NUMERALS

1 Vibrator
2 Magnet
4 Motor
5 Piston
6 Nozzle
7 Synthetic jet
8 Cabinet
9 Printed board
10 Heat generating element (electronic part)
11 Motor
12 Vibrator
13 Diaphragm
14 Air reservoir
15 Nozzle
16 Mobile telephone terminal
17 Duct
18 Reciprocal-type fan

1. A vibration generating and cooling apparatus, characterized by comprising:
a motor;
a magnetic eccentric plummet mounted onto a rotary shaft of the motor; and
a magnetic member indicating magnetism disposed physically apart from the eccentric plummet,
wherein the magnetic member repeatedly approaches and leaves the eccentric plummet in association with rotations of the eccentric plummet and a to-be-cooled object is cooled by a jet created by the movement of the magnetic member.

2. The vibration generating and cooling apparatus in accordance with claim 1, characterized in that
the magnetic member is a diaphragm arranged to enclose a predetermined space excepting at least one nozzle section, and
when the diaphragm deforms in association with the rotations of the eccentric plummet, fluid in the predetermined space is ejected as the jet from the nozzle section and is blown onto the to-be-cooled object.

3. The vibration generating and cooling apparatus in accordance with claim 1, characterized in that
the magnetic member is a piston arranged to enclose a predetermined space excepting at least one nozzle section, and
when the piston is dislocated in association with the rotations of the eccentric plummet, fluid in the predetermined space is ejected as the jet from the nozzle section and is blown onto the to-be-cooled object.

4. The vibration generating and cooling apparatus in accordance with claim 3, characterized in that the piston is monoblock-molded using a magnetic substance and a resin material.

5. The vibration generating and cooling apparatus in accordance with claim 3, characterized in that at least one of the nozzle sections is arranged to generate the jet in a direction different from a stroke direction of the piston.

6. The vibration generating and cooling apparatus in accordance with claim 1, characterized in that
the magnetic member is a swing fan disposed in a duct physically connected to a heat generating element and
a jet generated in the duct when the swing fan swings in association with the rotations of the eccentric plummet cools the duct heated through heat conduction from the heat generating element.

7. The vibration generating and cooling apparatus in accordance with claim 6, characterized in that projections and depressions are formed on an inner wall surface of the duct.
